(19) United States
(12) Patent Application Publication
(10) Pub. No.: US 2024/0324237 A1
(43) Pub. Date: Sep. 26, 2024

(54) THREE-DIMENSIONAL SEMICONDUCTOR MEMORY DEVICE

(71) Applicant: Samsung Electronics Co., Ltd., Suwon-si (KR)

(72) Inventors: Jeonil Lee, Suwon-si (KR); Kyunghwan Lee, Suwon-si (KR)

(21) Appl. No.: 18/608,149

(22) Filed: Mar. 18, 2024

(30) Foreign Application Priority Data
Mar. 24, 2023 (KR) 10-2023-0039223
May 2, 2023 (KR) 10-2023-0057351

(51) Int. Cl. H10B 53/20; H01L 21/28; H01L 29/51; H01L 29/78; H10B 51/10; H10B 51/20; H10B 51/40; H10B 53/10; H10B 53/40

(52) U.S. Cl. CPC H10B 53/20; H01L 29/40111; H01L 29/516; H01L 29/78391; H10B 51/10; H10B 51/20; H10B 51/40; H10B 53/10; H10B 53/40

(57) ABSTRACT

A three-dimensional (3D) semiconductor memory device includes a plurality of memory cells stacked in a vertical direction, each of the plurality of memory cells including a cell transistor and a cell capacitor. The cell capacitor includes a first electrode connected to a first source/drain region of the cell transistor, wherein a through hole is formed in the first electrode and the inner surface of the first electrode is formed in a shape having concave portions and convex portions in plan view, a capacitor insulating layer in the through hole, and a second electrode in the capacitor insulating layer and filling the through hole.

### CROSS-REFERENCE TO RELATED APPLICATION

This application is based on and claims priority under 35 U.S.C. § 119 to Korean Patent Application Nos. 10-2023-0039223, filed on Mar. 24, 2023 and 10-2023-0057351, filed on May 2, 2023, in the Korean Intellectual Property Office, the disclosures of which are incorporated by reference herein in their entireties.

### BACKGROUND

The inventive concept relates to a semiconductor memory device, and more particularly, to a three-dimensional (3D) semiconductor memory device.

As the miniaturization, multifunctionality, and high performance of electronic products become more and more in demand, high-capacity semiconductor memory devices are desirable. Because the degree of integration of a conventional two-dimensional (2D) semiconductor memory device is mainly determined by reduction in area occupied by a unit memory cell, an increase in the degree of integration of the 2D semiconductor memory device is limited by physical limitations of ultra-high-density semiconductor manufacturing processes. Accordingly, as a solution for increasing the degree of integration, a three-dimensional (3D) semiconductor memory device in which a plurality of memory cells are stacked in the vertical direction is attracting attention.

### SUMMARY

The inventive concept relates to a three-dimensional (3D) semiconductor memory device having an increased degree of integration and improved memory window characteristics.

According to an aspect of the inventive concept, there is provided a three-dimensional (3D) semiconductor memory device including a plurality of memory cells stacked in a vertical direction, each of the plurality of memory cells including a cell transistor and a cell capacitor, wherein the cell capacitor includes a first electrode connected to a first source/drain region of the cell transistor, wherein a through hole is formed in the first electrode and the inner surface of the first electrode is formed in a shape having concave portions and convex portions in plan view; a capacitor insulating layer in the through hole; and a second electrode in the capacitor insulating layer and filling the through hole.

According to another aspect of the inventive concept, there is provided a three-dimensional (3D) semiconductor memory device including a plurality of memory cells stacked in a vertical direction, the plurality of memory cells including a plurality of cell transistors and a plurality of cell capacitors, wherein the plurality of cell capacitors includes a plurality of sub-electrodes apart from one another in a vertical direction, wherein a through hole is formed in the plurality of sub-electrodes, and wherein an inner surface of each of the plurality of sub-electrodes is formed in a shape having concave portions and convex portions in plan view, and wherein the plurality of cell capacitors includes a capacitor insulating layer extending in the through hole in the vertical direction; and a second electrode extending in the capacitor insulating layer in the vertical direction and filling the through hole.

According to another aspect of the inventive concept, there is provided a three-dimensional (3D) semiconductor memory device includes a base layer; and a plurality of memory cell level layers apart from one another and stacked on the base layer in a vertical direction, wherein the plurality of memory cell level layers includes a plurality of cell transistors and a plurality of cell capacitors apart from one another in the vertical direction, wherein the plurality of cell transistors include source/drain regions; channel layers arranged among the source/drain regions; and gate electrodes arranged on the channel layers, wherein each of the plurality of cell capacitors includes a plurality of sub-electrodes apart from one another in a vertical direction, wherein a through hole is formed in the plurality of sub-electrodes, and wherein each of the plurality of sub-electrodes is formed in a shape having concave portions and convex portions in plan view, and wherein the plurality of cell capacitors include a capacitor insulating layer extending in the through hole in the vertical direction; and a second electrode extending in the capacitor insulating layer in the vertical direction and filling the through hole.

### BRIEF DESCRIPTION OF THE DRAWINGS

Embodiments will be more clearly understood from the following detailed description taken in conjunction with the accompanying drawings in which:

FIG. 1 is a schematic circuit diagram illustrating a three-dimensional (3D) semiconductor memory device according to an embodiment;

FIG. 2 is a cross-sectional view of a main part of a 3D semiconductor memory device according to an embodiment;

FIG. 3A is a plan view of a main part of a 3D semiconductor memory device according to an embodiment;

FIG. 3B is an enlarged view of a cell capacitor of FIG. 3A;

FIG. 3C is a plan view illustrating a through hole formed in a first electrode of the cell capacitor of FIG. 3A;

FIGS. 4 to 17 are views illustrating a method of manufacturing a 3D semiconductor memory device, according to an embodiment; and

FIG. 18 is a cross-sectional view of a main part of a 3D semiconductor memory device according to an embodiment.

### DETAILED DESCRIPTION OF THE EMBODIMENTS

Hereinafter, embodiments of the inventive concept will be described in detail with reference to the accompanying drawings. The following embodiments may be implemented by only one embodiment, or may be implemented by combining one or more embodiments. Therefore, the technical spirit of the inventive concept should not be construed as being limited to one embodiment.

In the current specification, singular forms of components may include plural forms unless the context clearly indicates otherwise. In the current specification, the drawings are exaggerated in order to more clearly explain the inventive concept. In the current specification, the expression “connected” may mean electrically and/or physically connected. In the current specification, first to nth components (n is a positive integer) are used for convenience of description, and the order of the components does not limit the technical spirit of the inventive concept.

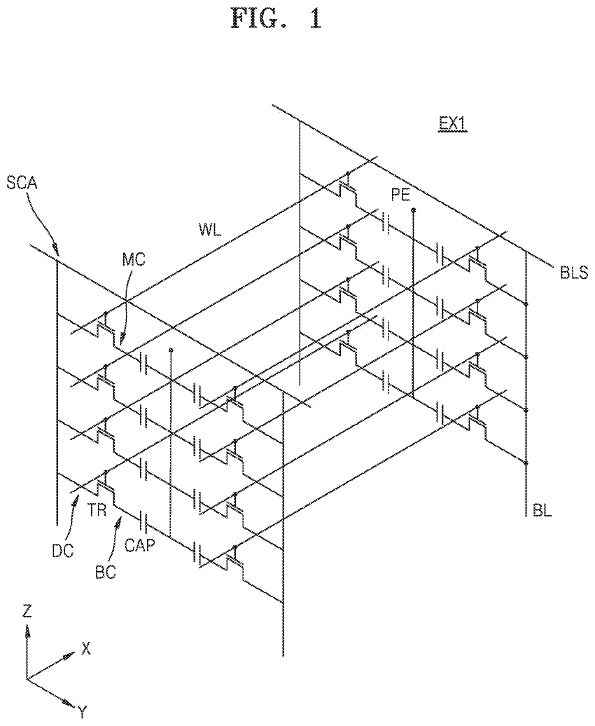

FIG. 1 is a schematic circuit diagram illustrating a three-dimensional (3D) semiconductor memory device EX1 according to an embodiment.

Specifically, the 3D semiconductor memory device EX1 may include a plurality of memory cells MC stacked in the vertical direction (a third direction, e.g., a Z direction). The plurality of memory cells MC may include cell transistors TR and cell capacitors CAP. The cell transistors TR and the cell capacitors CAP may be connected to each other. First source/drain regions of the cell transistors TR may be connected to first electrodes of the cell capacitors CAP through buried contacts BC.

An item, layer, or portion of an item or layer described as extending “lengthwise” in a particular direction has a length in the particular direction and a width perpendicular to that direction, where the length is greater than the width.

The plurality of memory cells MC may constitute a plurality of sub-cell arrays SCA. In some embodiments, the plurality of sub-cell arrays SCA may be arranged in a first direction (X direction). A plurality of word lines WL may extend in the first direction (the X direction). Each of the plurality of sub-cell arrays SCA may include the plurality of memory cells MC. In each of the plurality of sub-cell arrays SCA, the plurality of memory cells MC may be apart from one another in a second direction (Y direction) and the third direction (the Z direction).

A plurality of bit line straps BLS may extend in the second direction (the Y direction). A plurality of bit lines BL may extend in the third direction (the Z direction). On an X-Y plane, the second direction (the Y direction) may be substantially perpendicular to the first direction (the X direction). The third direction (the Z direction) may be substantially perpendicular to the first direction (the X direction) and the second direction (the Y direction). The first direction (the X direction) may be referred to as a first horizontal direction. The second direction (the Y direction) may be referred to as a second horizontal direction. The third direction (the Z direction) may be referred to as the vertical direction.

The plurality of memory cells MC may share second electrodes PE of the cell capacitors CAP. The cell capacitors CAP may share the second electrodes PE extending in the third direction (the Z direction). In other words, the second electrodes PE may include common electrodes of the cell capacitors CAP arranged in the third direction (the Z direction). The plurality of word lines WL may extend in the first direction (the X direction) and may be arranged in the second direction (the Y direction) and the third direction (the Z direction).

The plurality of bit lines BL may be arranged in the first direction (the X direction) and the second direction (the Y direction) and may extend in the third direction (the Z direction). The plurality of bit lines BL may be connected to the cell transistors TR.

Second source/drain regions of the cell transistors TR may be connected to the plurality of bit lines BL through direct contacts DC. The plurality of bit line straps BLS may be arranged in the first direction (the X direction) and may extend in the second direction (the Y direction). The plurality of bit lines BL may be connected to the plurality of bit line straps BLS. The plurality of bit line straps BL may be connected to the plurality of bit lines BL arranged in the first direction (the X direction) and the second direction (the Y direction).

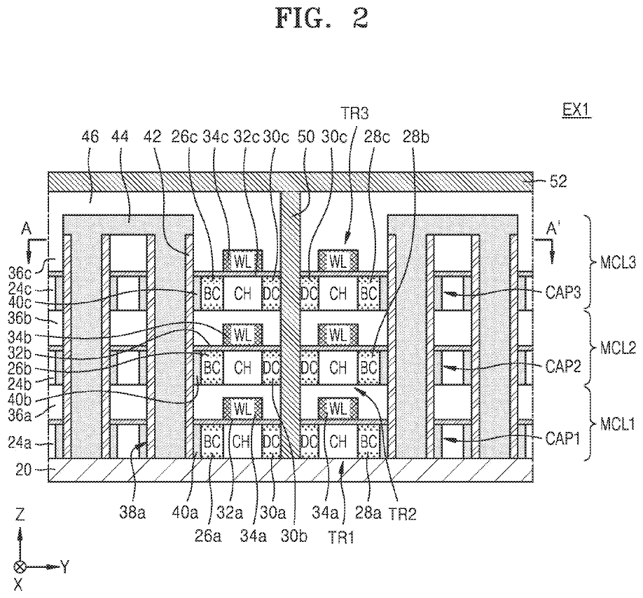

FIG. 2 is a cross-sectional view of a main part of a 3D semiconductor memory device EX1 according to an embodiment.

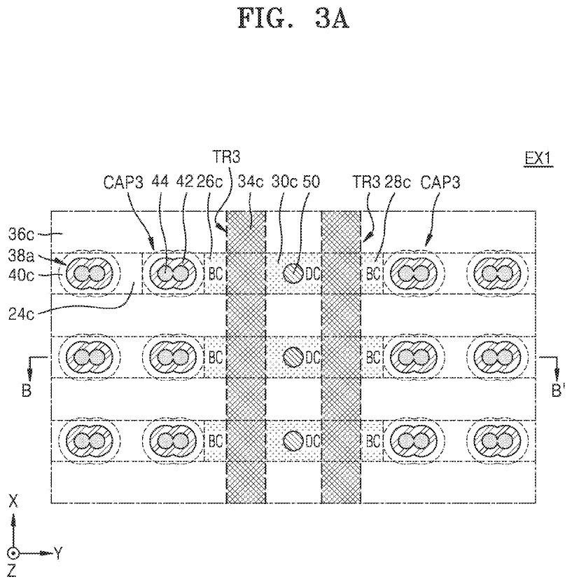

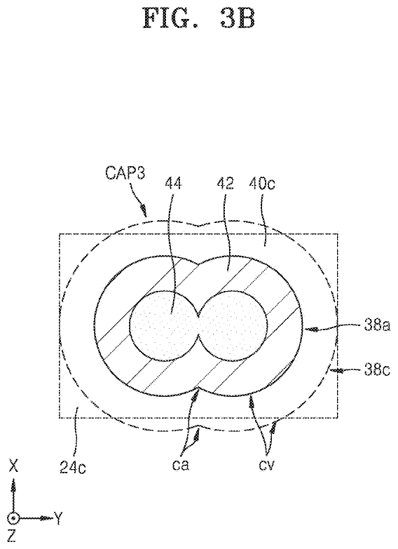

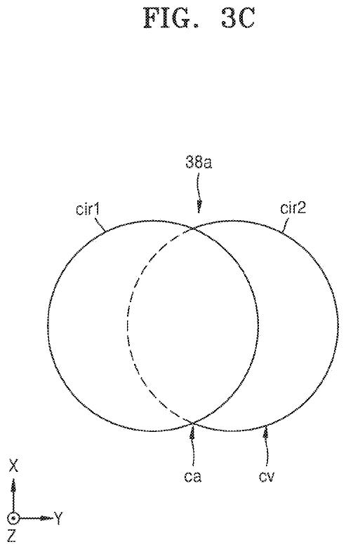

Specifically, FIG. 2 may illustrate an example of implementing the 3D semiconductor memory device EX1 of FIG. 1. The 3D semiconductor memory device EX1 illustrated in FIG. 2 may be a schematic cross-sectional view of a main part taken along the line B-B′ of FIG. 3A.

The 3D semiconductor memory device EX1 may include first to third memory cell level layers MCL1, MCL2, and MCL3 apart from one another and sequentially stacked on a base layer 20 in the vertical direction (the Z direction). The base layer 20 may be formed of or include an insulating layer. The insulating layer may include a silicon oxide layer or a silicon nitride layer. In some embodiments, the base layer 20 may include a material layer formed on a semiconductor substrate.

In the current embodiment, the three memory cell level layers MCL1, MCL2, and MCL3 are illustrated. However, the inventive concept is not limited thereto and two or more memory cell level layers may be stacked on the base layer 20.

The first memory cell level layer MCL1 may include a first cell transistor TR1, a first cell capacitor CAP1, a first active layer 24a, and a first interlayer insulating layer 36a. The first cell transistor TR1 and the first cell capacitor CAP1 may correspond to the cell transistor TR and the cell capacitor CAP of FIG. 1, respectively. The first cell transistor TR1 and the first cell capacitor CAP1 may be symmetrically arranged on both sides of a bit line 50 in a Y-Z cross-section. For example, one first cell transistor TR1 and one first cell capacitor CAP1 may be arranged on one side of the bit line 50 and another first cell transistor TR1 and another first cell capacitor CAP1 may be arranged on the other side of the bit line 50 as shown, e.g., in FIG. 2. The bit line 50 may correspond to the bit line BL of FIG. 1. The bit line 50 may include a metal material, for example, tungsten (W).

For example, the first cell transistor TR1 and the first cell capacitor CAP1 may be sequentially arranged on the right side of the bit line 50. The first cell transistor TR1 and the first cell capacitor CAP1 may be sequentially arranged on the left side of the bit line 50. The first interlayer insulating layer 36a may cover the first cell transistor TR1 and the first cell capacitor CAP1. The first interlayer insulating layer 36a may be formed of or include a silicon oxide layer or a silicon nitride layer.

The first cell transistor TR1 may include a first gate insulating layer 32a, a first gate electrode 34a, a first source/drain region 26a or 28a, a second source/drain region 30a, and a channel layer CH. The first source/drain region 26a or 28a, the second source/drain region 30a, and the channel layer CH may be formed in the first active layer 24a. The channel layer CH may be formed of or include a semiconductor material, a two-dimensional (2D) material, or an oxide semiconductor material.

In some embodiments, the semiconductor material may include single crystal silicon (Si), polysilicon, silicon germanium (SiGe), or silicon carbide (SiC). The 2D material may include 2D transition metal dichalcogenide (TMD). The 2D TMD basically has a chemical formula of MX2, in which M is a transition metal element and X is a chalcogen element. M may include molybdenum (Mo), W, vanadium (V), niobium (Nb), tantalum (Ta), or titanium (Ti) of groups 4 to 10 on the periodic table, and X may include sulfur (S), selenium (Se), or tellurium (Te) of group 16 on the periodic table.

The oxide semiconductor material may include CuS₂, CuSe₂, WSe₂, MoS₂, MoSe₂, WS₂, indium zinc oxide (IZO), zinc tin oxide (ZTO), yttrium zinc oxide (YZO), or indium gallium zinc oxide (IGZO). The channel layer CH may include the same material as the first active layer 24a.

For example, the first cell transistor TR1 may include the first gate electrode 34a, the first gate insulating layer 32a, the first source/drain region 28a, the second source/drain region 30a, and the channel layer CH positioned on the right side of the bit line 50. The first cell transistor TR1 may include the first gate insulating layer 32a, the first gate electrode 34a, the first source/drain region 26a, the second source/drain region 30a, and the channel layer CH positioned on the left side of the bit line 50.

The first gate insulating layer 32a may be formed of or include silicon oxide or silicon nitride. The first gate insulating layer 32a may include hafnium oxide or a high dielectric layer having a high dielectric constant. The first gate electrode 34a may correspond to the word line WL of FIG. 1. The first gate electrode 34a may be formed of or include a metal material.

The first source/drain region 26a or 28a may constitute a buried contact BC connected to the first cell capacitor CAP1. The second source/drain region 30a may constitute a direct contact DC connected to the bit line 50. The channel layer CH may be formed under the first gate electrode 34a.

The first cell capacitor CAP1 may include a first sub-electrode 40a, a capacitor insulating layer 42, and a second electrode 44. The second electrode 44 may correspond to the second electrode PE of FIG. 1. The first sub-electrode 40a may include a first electrode of the first cell capacitor CAP1. The first sub-electrode 40a may be recessed from one end of the first gate insulating layer 32a or the first interlayer insulating layer 36a in cross-section. For example, a side surface of the first sub-electrode 40a may be coplanar with side surfaces of the first gate insulating layer 32a and/or the first interlayer insulating layer 36a.

The first sub-electrode 40a may be formed in an embossed shape such that an inner surface of the first sub-electrode 40a has concave portions and convex portions in a plan view as described later. A through hole 38a may be formed in the first sub-electrode 40a. The capacitor insulating layer 42 may be formed in the first sub-electrode 40a. The second electrode 44 may be formed in the capacitor insulating layer 42. For example, the capacitor insulating layer 42 may be formed in the through hole 38a and may line the inner walls of the first sub-electrode 40a. For example, the second electrode 44 may fill all or a part of the remaining portion of the through hole 38a that is not filled by the capacitor insulating layer 42.

In some embodiments, the capacitor insulating layer 42 may be formed of or include a ferroelectric layer. In some embodiments, the ferroelectric layer may include a hafnium-based oxide layer including at least one dopant among zirconium (Zr), Si, aluminum (Al), yttrium (Y), gadolinium (Gd), lanthanum (La), scandium (Sc), and strontium (Sr). In some embodiments, the capacitor insulating layer 42 may include a stacked structure of two or more types of ferroelectric layers or a stacked structure of a ferroelectric layer and a dielectric layer. In some embodiments, the capacitor insulating layer 42 may include silicon oxide, silicon nitride, or hafnium oxide. When the capacitor insulating layer 42 includes a ferroelectric layer, the 3D semiconductor memory device EX1 may include a 3D ferroelectric semiconductor memory device.

The second memory cell level layer MCL2 may include a second cell transistor TR2, a second cell capacitor CAP2, a second active layer 24b, and a second interlayer insulating layer 36b. The second cell transistor TR2 and the second cell capacitor CAP2 may correspond to the cell transistor TR and the cell capacitor CAP of FIG. 1, respectively. The second cell transistor TR2 and the second cell capacitor CAP2 may be symmetrically arranged on both sides of the bit line 50 in the Y-Z cross-section. For example, one second cell transistor TR2 and one second cell capacitor CAP2 may be arranged on one side of the bit line 50 and another second cell transistor TR2 and another second cell capacitor CAP2 may be arranged on the other side of the bit line 50 as shown, e.g., in FIG. 2.

For example, the second cell transistor TR2 and the second cell capacitor CAP2 may be sequentially arranged on the right side of the bit line 50. The second cell transistor TR2 and the second cell capacitor CAP2 may be sequentially arranged on the left side of the bit line 50. The second interlayer insulating layer 36b may cover the second cell transistor TR2 and the second cell capacitor CAP2. The second interlayer insulating layer 36b may include a silicon oxide layer or a silicon nitride layer.

The second cell transistor TR2 may include a second gate insulating layer 32b, a second gate electrode 34b, a third source/drain region 26b or 28b, a fourth source/drain region 30b, and a channel layer CH. The third source/drain region 26b or 28b, the fourth source/drain region 30b, and the channel layer CH may be formed in the second active layer 24b. The channel layer CH may be formed of the above-described material. The channel layer CH may be formed of the same material as the second active layer 24b.

For example, the second cell transistor TR2 may include the second gate electrode 34b, the second gate insulating layer 32b, the third source/drain region 28b, the fourth source/drain region 30b, and the channel layer CH located on the right side of the bit line 50. The second cell transistor TR2 may include the second gate insulating layer 32b, the second gate electrode 34b, the third source/drain region 26b, the fourth source/drain region 30b, and the channel layer CH positioned on the left side of the bit line 50.

The second gate insulating layer 32b and the second gate electrode 34b may be formed of the same material as the first gate insulating layer 32a and the first gate electrode 34a, respectively. The second gate electrode 34b may correspond to the word line WL of FIG. 1. The third source/drain region 26b or 28b may constitute a buried contact BC connected to the second cell capacitor CAP2. The fourth source/drain region 30b may constitute a direct contact DC connected to the bit line 50. The channel layer CH may be formed under the second gate electrode 34b.

The second cell capacitor CAP2 may include a second sub-electrode 40b, a capacitor insulating layer 42, and a second electrode 44. The second sub-electrode 40b may include a first electrode of the second cell capacitor CAP2. The second sub-electrode 40b may be recessed from one end of the second gate insulating layer 32b or the second interlayer insulating layer 36b in cross-section. For example, a side surface of the second sub-electrode 40b may be coplanar with side surfaces of the second gate insulating layer 32b and/or the second interlayer insulating layer 36b.

The second sub-electrode 40b may be formed in an embossed shape in a plan view as described below. A through hole 38a may be formed in the second sub-electrode 40b. The capacitor insulating layer 42 may be formed in the second sub-electrode 40b. The second electrode 44 may be formed in the capacitor insulating layer 42. For example, the capacitor insulating layer 42 may be formed in the through hole 38a and may line the inner walls of the second sub-electrode 40b. For example, the second electrode 44 may fill all or a part of the remaining portion of the through hole 38a that is not filled by the capacitor insulating layer 42.

The third memory cell level layer MCL3 may include a third cell transistor TR3, a third cell capacitor CAP3, a third active layer 24c, and a third interlayer insulating layer 36c. The third cell transistor TR3 and the third cell capacitor CAP3 may correspond to the cell transistor TR and the cell capacitor CAP of FIG. 1, respectively. The third cell transistor TR3 and the third cell capacitor CAP3 may be symmetrically arranged on both sides of the bit line 50 in the Y-Z cross-section. For example, one third cell transistor TR3 and one third cell capacitor CAP3 may be arranged on one side of the bit line 50 and another third cell transistor TR3 and another third cell capacitor CAP3 may be arranged on the other side of the bit line 50 as shown, e.g., in FIG. 2.

For example, the third cell transistor TR3 and the third cell capacitor CAP3 may be sequentially arranged on the right side of the bit line 50. The third cell transistor TR3 and the third cell capacitor CAP3 may be sequentially arranged on the left side of the bit line 50. The third interlayer insulating layer 36c may cover the third cell transistor TR3 and the third cell capacitor CAP3. The third interlayer insulating layer 36c may include a silicon oxide layer or a silicon nitride layer.

The third cell transistor TR3 may include a third gate insulating layer 32c, a third gate electrode 34c, a fifth source/drain region 26c or 28c, a sixth source/drain region 30c, and a channel layer CH. The fifth source/drain region 26c or 28c, the sixth source/drain region 30c, and the channel layer CH may be formed in the third active layer 24c. The channel layer CH may be formed of the above-described material. The channel layer CH may be formed of the same material as the third active layer 24c.

For example, the third cell transistor TR3 may include the third gate electrode 34c, the third gate insulating layer 32c, the fifth source/drain region 28c, the sixth source/drain region 30c, and the channel layer CH positioned on the right side of the bit line 50. The third cell transistor TR3 may include the third gate insulating layer 32c, the third gate electrode 34c, the fifth source/drain region 26c, the sixth source/drain region 30c, and the channel layer CH positioned on the left side of the bit line 50.

The third gate insulating layer 32c and the third gate electrode 34c may be formed of the same material as the first gate insulating layer 32a and the first gate electrode 34a, respectively. The third gate electrode 34c may correspond to the word line WL of FIG. 1. The fifth source/drain region 26c or 28c may constitute a buried contact BC connected to the third cell capacitor CAP3. The sixth source/drain region 30c may constitute a direct contact DC connected to the bit line 50. The channel layer CH may be formed under the third gate electrode 34c.

The third cell capacitor CAP3 may include a third sub-electrode 40c, a capacitor insulating layer 42, and a second electrode 44. The third sub-electrode 40c may include a first electrode of the third cell capacitor CAP3. The third sub-electrode 40c may be recessed from one end of the third gate insulating layer 32c or the third interlayer insulating layer 36c in cross-section. For example, a side surface of the third sub-electrode 40c may be coplanar with side surfaces of the third gate insulating layer 32c and/or the third interlayer insulating layer 36c.

The third sub-electrode 40c may be formed in an embossed shape in a plan view as described below. A through hole 38a may be formed in the third sub-electrode 40c. The capacitor insulating layer 42 may be formed in the third sub-electrode 40c. The second electrode 44 may be formed in the capacitor insulating layer 42. For example, the capacitor insulating layer 42 may be formed in the through hole 38a and may line the inner walls of the third sub-electrode 40c. For example, the second electrode 44 may fill all or a part of the remaining portion of the through hole 38a that is not filled by the capacitor insulating layer 42.

The first to third cell capacitors CAP1, CAP2, and CAP3 may share the capacitor insulating layer 42 and the second electrode 44. The capacitor insulating layer 42 and the second electrode 44 may extend in the third direction (the Z direction) perpendicular to the base layer 20. In addition, the second electrode 44 may be connected to cell capacitors adjacent to one another in the second direction (the Y direction).

The first to third cell transistors TR1, TR2, and TR3 may share the bit line 50. The bit line 50 may extend in the third direction (the Z direction) perpendicular to the base layer 20. A bit line strap 52 extending in the second direction (the Y direction) may be formed on the bit line 50. The bit line strap 52 may be formed of a metal material, for example, W. The bit line strap 52 may be connected to the bit line 50. The bit line strap 52 may correspond to the bit line strap BLS of FIG. 1.

The first to third memory cell level layers MCL1, MCL2, and MCL3 of the 3D semiconductor memory device EX1 may respectively include first to third cell transistors TR1, TR2, and TR3 and first to third cell capacitors CAP1, CAP2, and CAP3 arranged apart from one another in the vertical direction (the Z direction).

The first to third cell transistors TR1, TR2, and TR3 may include first, second, third, fourth, fifth, and sixth source/drain regions 26a or 28a, 30a, 26b or 28b, 30b, 26c or 28c, and 30c, channel layers CH arranged among the first, second, third, fourth, fifth, and sixth source/drain regions 26a or 28a, 30a, 26b or 28b, 30b, 26c or 28c, and 30c, and first, second, and third gate electrodes 34a, 34b, and 34c arranged on the channel layers CH.

Each of the first to third cell capacitors CAP1, CAP2, and CAP3 respectiely includes a first electrode formed of each of first to third sub-electrodes 40a, 40b, and 40c apart from one another in the vertical direction (the Z direction). The through hole 38a is formed in the first to third sub-electrodes 40a, 40b, and 40c, and each of the first to third sub-electrodes 40a, 40b, and 40c may be formed in an embossed shape in a plan view as described below.

The first to third cell capacitors CAP1, CAP2, and CAP3 may include the capacitor insulating layer 42 extending in the through hole 38a in the vertical direction (the Z direction). The first to third cell capacitors CAP1, CAP2, and CAP3 may include the second electrode 44 extending in the capacitor insulating layer 42 in the vertical direction (the Z direction) while filling the through hole 38a.

FIG. 3A is a plan view of a main part of a 3D semiconductor memory device according to an embodiment, FIG. 3B is an enlarged view of the cell capacitor of FIG. 3A, and FIG. 3C is a plan view for describing a through hole formed in a first electrode of the cell capacitor of FIG. 3A.

Specifically, FIGS. 3A to 3C may illustrate an example of implementing the 3D semiconductor memory device EX1 of FIG. 1. The 3D semiconductor memory device EX1 illustrated in FIG. 3A may be a schematic plan view of a main part taken along the line A-A′ of FIG. 2. For convenience, the 3D semiconductor memory device EX1 illustrated in FIG. 3A additionally includes the third sub-electrode 40c illustrated in FIG. 2. In FIGS. 3A to 3C, description previously given with reference to FIG. 2 is simply given or omitted.

The 3D semiconductor memory device EX1 illustrated in FIG. 3A mainly illustrates the third memory cell level layer MCL3 of FIG. 2 on the X-Y plane. The third memory cell level layer MCL3 of FIG. 2 may include the third cell transistor TR3 and the third cell capacitor CAP3. The third cell transistor TR3 and the third cell capacitor CAP3 may be symmetrically arranged on both sides of the bit line 50 on the X-Y plane.

For example, the third cell transistor TR3 and the third cell capacitor CAP3 may be sequentially arranged on the left side of the bit line 50. The third cell transistor TR3 and the third cell capacitor CAP3 may be sequentially arranged on the right side of the bit line 50.

The third cell transistor TR3 arranged on the left side of the bit line 50 on the X-Y plane may include the third gate electrode 34c, the fifth source/drain region 26c, and the sixth source/drain region 30c. The third cell transistor TR3 arranged on the right side of the bit line 50 on the X-Y plane may include the third gate electrode 34c, the fifth source/drain region 28c, and the sixth source/drain region 30c. The fifth source/drain region 26c or 28c and the sixth source/drain region 30c may extend in the second direction (the Y direction). For example, the fifth source/drain region 26c or 28c may extend in the second direction between the third sub-electrode 40c and the channel layer CH. For example, the sixth source/drain region 30c may extend in the second direction between the channel layer CH on the right side of the bit line 50 and the channel layer CH on the left side of the bit line 50.

The fifth source/drain region 26c or 28c, the sixth source/drain region 30c, and the channel layer CH may be formed in the third active layer 24c. The third active layer 24c may extend in the second direction (the Y direction). The third cell transistor TR3 and the third cell capacitor CAP3 may be aligned in the second direction (the Y direction).

For example, in the third cell transistor TR3, the fifth source/drain region 26c or 28c, the sixth source/drain region 30c, and the channel layer CH of FIG. 2 may be arranged in the second direction (the Y direction). The center lines of the fifth source/drain region 26c or 28c, the sixth source/drain region 30c, and the channel layer CH of FIG. 2 may coincide with the center line of the third cell capacitor CAP3.

The third gate electrode 34c may constitute the word line WL of FIG. 1. The third gate electrode 34c may extend in the first direction (the X direction). The fifth source/drain region 26c or 28c may constitute a buried contact BC connected to the third cell capacitor CAP3. The sixth source/drain region 30c may constitute a direct contact DC connected to the bit line 50.

The third cell capacitor CAP3 may include a third sub-electrode 40c, a capacitor insulating layer 42, and a second electrode 44. The third sub-electrode 40c may include a first electrode of the third cell capacitor CAP3. The shape of the third sub-electrode 40c may be the same as that of each of the first sub-electrode 40a and the second sub-electrode 40b on the X-Y plane.

As illustrated in FIG. 3B, the third sub-electrode 40c may be formed in a recess hole 38c obtained by extending the through hole 38a on the X-Y plane. The recess hole 38c may be formed by further horizontally etching the through hole 38a on the X-Y plane as described below. The recess hole 38c may have concave portions ca and convex portions cv on the X-Y plane. The recess hole 38c may be formed in an embossed shape on the X-Y plane. For example, the recess hole 38c may have a shape of two partially overlapping symmetrical geometric shapes (e.g., ovals or circles) in plan view.

The third sub-electrode 40c may be formed in the recess hole 38c. As illustrated in FIG. 3B, the through hole 38a may be formed in the third sub-electrode 40c. The through hole 38a may be formed in an embossed shape having concave portions ca and convex portions cv on the X-Y plane. As illustrated in FIG. 3C, in the through hole 38a, a plurality of sub-through holes, for example, a first sub-through hole cir1 and a second sub-through hole cir2, partially overlap each other in one direction (the second direction (the Y direction)) on the X-Y plane.

For example, each of the plurality of sub-through holes may have a symmetrical geometric shape and the symmetrical geometric shapes may partially overlap. For example, each of the plurality of sub-through holes may have a circle or an oval shape.

The distance from a geometric center of the first sub-through hole cir1 to a geometric center of the second sub-through hole cir2 may be less than the width of the first sub-through hole cir1 and less than the width of the second sub-through hole cir2. For example, the distance from a geometric center of the first sub-through hole cir1 to a geometric center of the second sub-through hole cir2 may be less than a distance from the geometric center of the first sub-through hole cir1 to the edge of the first sub-through hole cir1 and less than a distance from the geometric center of the second sub-through hole cir2 to an edge of the second sub-through hole cir2.

Each of the plurality of sub-through holes may correspond to a through hole as defined in a standard cell library. For example, one or more through holes may be formed elsewhere in the 3D semiconductor memory device that have the shape of a single one of the plurality of sub-through holes described above.

Accordingly, the third sub-electrode 40c may be formed in an embossed shape having concave portions ca and convex portions cv on the X-Y plane. The concave portions ca and the convex portions cv may be formed on both the outer surface and the inner surface of the third sub-electrode 40c on the X-Y plane. In some embodiments, the third sub-electrode 40c may be formed in a cloud shape on the X-Y plane. The cloud shape may be formed when the plurality of sub-through holes (e.g., three or more of the sub-through holes) described above overlap one another instead of two.

The capacitor insulating layer 42 may be formed in the through hole 38a. The capacitor insulating layer 42 may be formed in the embossed shape according to the shape of the third sub-electrode 40c. The second electrode 44 may be formed in the capacitor insulating layer 42 while filling the through hole 38a. The second electrode 44 may be formed in the embossed shape according to the shape of the third sub-electrode 40c. For example, each of the capacitor insulating layer 42 and the second electrode 44 may be formed in a shape corresponding to the shape of the third sub-electrode 40c.

As described above, the third cell capacitor CAP3 may include the capacitor insulating layer 42 and the second electrode 44 formed in the third sub-electrode 40c. The third sub-electrode 40c, that is, the first electrode, may constitute an outer electrode on the X-Y plane, and the second electrode 44 may constitute an inner electrode on the X-Y plane.

The third cell capacitor CAP3 may include one third sub-electrode 40c (the first electrode), one capacitor insulating layer 42, and one second electrode 44 on the X-Y plane.

The 3D semiconductor memory device EX1 according to the inventive concept as described above may include the first to third cell transistors TR1, TR2, and TR3 and the first to third cell capacitors CAP1, CAP2, and CAP3 stacked in the vertical direction to increase the degree of integration. In addition, the 3D semiconductor memory device EX1 according to the inventive concept includes the first electrode constituting each of the first to third cell capacitors CAP1, CAP2, and CAP3, that is, the first to third sub-electrodes 40a, 40b, and 40c, each formed in the embossed shape having the concave portions ca and the convex portions cv on the X-Y plane. Accordingly, the 3D semiconductor memory device EX1 may improve memory window characteristics by increasing cell capacitance.

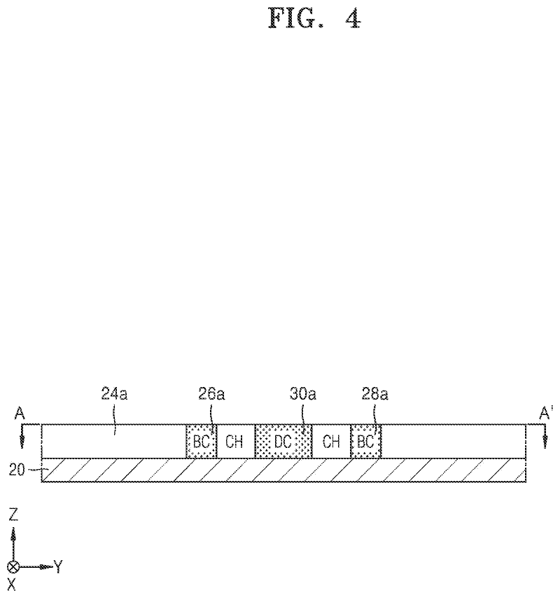

FIGS. 4 to 17 are views illustrating a method of manufacturing a 3D semiconductor memory device, according to an embodiment.

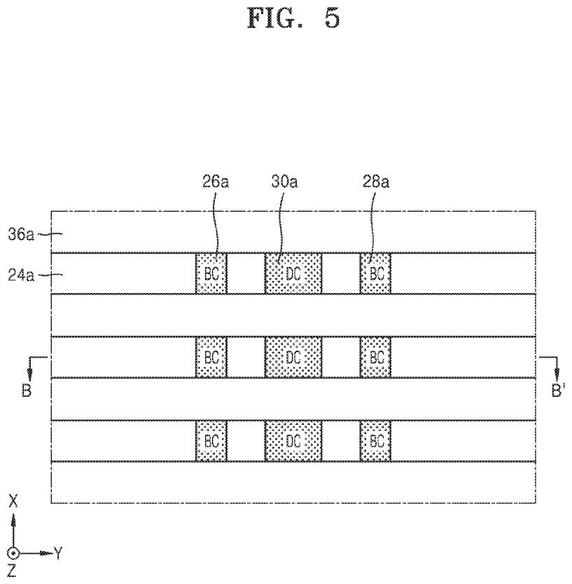

Specifically, FIGS. 4 to 17 are views illustrating a method of manufacturing the 3D semiconductor memory device of FIGS. 2 to 3C. FIGS. 4, 6, 8, 10, 12, 14, and 16 are cross-sectional views illustrating the method of manufacturing the 3D semiconductor memory device of FIG. 2, and FIGS. 5, 7, 9, 11, 13, 15, and 17 are plan views illustrating the method of manufacturing the 3D semiconductor memory device of FIG. 3A.

FIGS. 4, 6, 8, 10, 12, 14, and 16 are cross-sectional views taken along the line B-B′ of FIGS. 5, 7, 9, 11, 13, 15, and 17, respectively. FIGS. 5, 7, 9, 11, 13, 15, and 17 are plan views taken along the line A-A′ of FIGS. 4, 6, 8, 10, 12, 14, and 16, respectively.

In FIGS. 4 to 17, the same reference numerals as those in FIGS. 2 to 3C denote the same members. In FIGS. 4 to 17, description previously given with reference to FIGS. 2 to 3C is simply given or omitted.

Referring to FIGS. 4 and 5, as illustrated in FIG. 5, first interlayer insulating layers 36a are formed on the base layer 20 of FIG. 4. As illustrated in FIG. 5, the first interlayer insulating layers 36a extend in the second direction (the Y direction). The first interlayer insulating layers 36a include a plurality of insulating patterns separated from one another in the first direction (the X direction). The first interlayer insulating layers 36a may be formed by forming first interlayer insulating material layers on the base layer 20 of FIG. 4 and patterning the first interlayer insulating material layers.

As illustrated in FIG. 5, the first active layers 24a are formed among the first interlayer insulating layers 36a. The first active layers 24a may extend in the second direction (the Y direction). The first active layers 24a include a plurality of active patterns separated from one another in the first direction (the X direction). The first active layers 24a may be formed by forming active material layers among the first interlayer insulating layers 36a including the plurality of insulating patterns and planarizing the active material layers.

Subsequently, first source/drain regions 26a and 28a and second source/drain regions 30a are formed on the first active layers 24a. The first source/drain regions 26a and 28a and the second source/drain regions 30a may be formed by implanting impurities into the first active layers 24a. The first source/drain regions 26a and 28a may be separated from each other. The first source/drain regions 26a and 28a may be separated from the second source/drain regions 30a.

In this case, as illustrated in FIG. 4, the first active layer 24a may be formed on the base layer 20, and the first source/drain regions 26a and 28a and the second source/drain region 30a may be formed in the first active layer 24a. The first source/drain regions 26a and 28a may constitute or include buried contacts BC connected to cell capacitors, and the second source/drain region 30a may constitute or include a direct contact DC connected to a bit line.

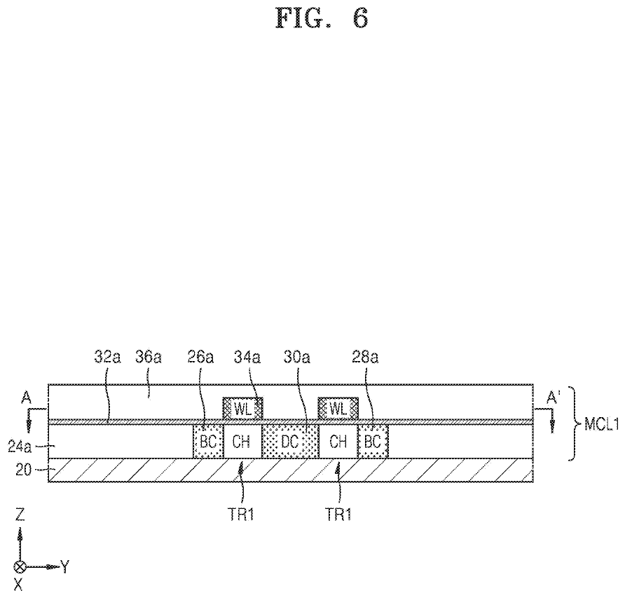

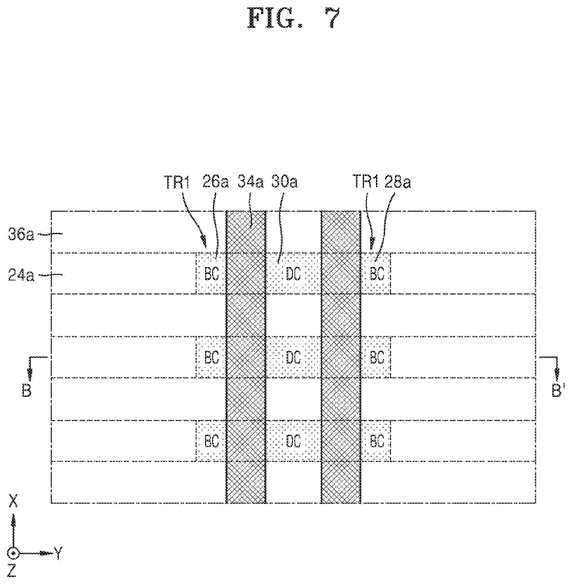

Referring to FIGS. 6 and 7, as illustrated in FIG. 6, the first gate insulating layer 32a is formed on the first active layer 24a. The first gate electrodes 34a are formed on the first gate insulating layer 32a. The first gate electrodes 34a are formed by forming a metal material layer on the first gate insulating layer 32a and patterning the metal material layer.

The first gate electrodes 34a may include a plurality of metal patterns apart from one another. The first gate electrodes 34a may correspond to the word lines WL. According to the formation of the first gate electrode 34a, the channel layer CH may be formed between the first source/drain region 26a and the second source/drain region 30a. The first gate electrode 34a, the first source/drain region 26a, the second source/drain region 30a, and the channel layer CH constitute the first cell transistor TR1.

According to the formation of the first gate electrode 34a, the channel layer CH may also be formed in the first active layer 24a between the first source/drain region 28a and the second source/drain region 30a. The first gate electrode 34a, the first source/drain region 28a, the second source/drain region 30a, and the channel layer CH also constitute the first cell transistor TR1.

Subsequently, the first interlayer insulating layer 36a is formed entirely on the first gate electrode 34a and the first gate insulating layer 32a to form the first memory cell level layer MCL1.

As illustrated in FIG. 7, the first gate electrodes 34a extend in the first direction (the X direction). The metal patterns constituting the first gate electrodes 34a extend in the first direction (the X direction) and are apart from each other in the second direction (the Y direction).

The first gate electrode 34a, the first source/drain region 26a, the second source/drain region 30a, and the channel layer CH of FIG. 6 under the first gate electrode 34a constitute the first cell transistor TR1. The first gate electrode 34a, the first source/drain region 28a, the second source/drain region 30a, and the channel layer CH of FIG. 6 under the first gate electrode 34a also constitute the first cell transistor TR1.

The first source/drain regions 26a and 28a, the second source/drain region 30a, and the channel layers CH of FIG. 6 under the first gate electrodes 34a are arranged in the second direction (the Y direction) like the first active layer 24a.

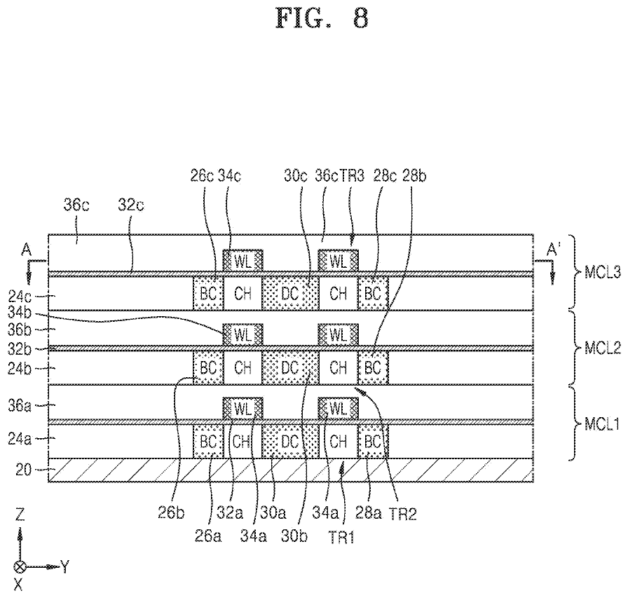

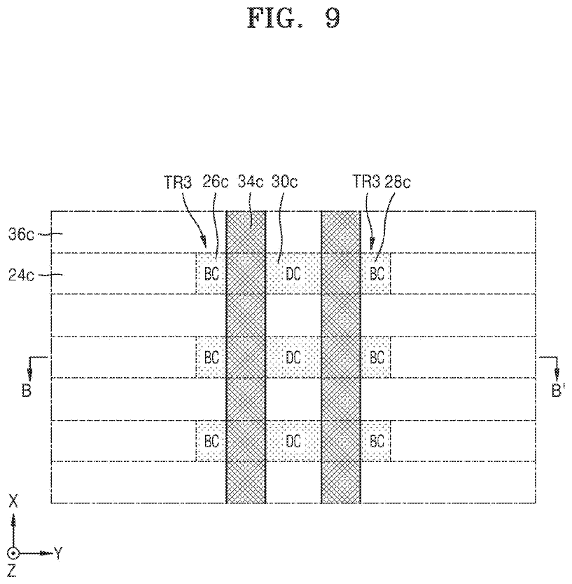

Referring to FIGS. 8 and 9, as illustrated in FIG. 8, the second memory cell level layer MCL2 and the third memory cell level layer MCL3 are sequentially formed on the first memory cell level layer MCL1. The second memory cell level layer MCL2 and the third memory cell level layer MCL3 may be formed by repeating the manufacturing processes of FIGS. 4 to 7.

The second memory cell level layer MCL2 may include the second cell transistor TR2, the second active layer 24b, and the second interlayer insulating layer 36b. The second cell transistor TR2 may include the second gate insulating layer 32b, the second gate electrode 34b, the third source/drain region 26b or 28b, the fourth source/drain region 30b, and the channel layer CH.

The third memory cell level layer MCL3 may include the third cell transistor TR3, the third active layer 24c, and the third interlayer insulating layer 36c. The third cell transistor TR3 may include the third gate insulating layer 32c, the third gate electrode 34c, the fifth source/drain region 26c or 28c, the sixth source/drain region 30c, and the channel layer CH.

As illustrated in FIG. 9, the third gate electrodes 34c extend in the first direction (the X direction). The metal patterns constituting the third gate electrodes 34c extend in the first direction (the X direction) and are apart from each other in the second direction (the Y direction).

The third gate electrode 34c, the fifth source/drain region 26c, the sixth source/drain region 30c, and the channel layer CH of FIG. 8 under the third gate electrode 34c constitute the third cell transistor TR3. The third gate electrode 34c, the fifth source/drain region 28c, the sixth source/drain region 30c, and the channel layer CH of FIG. 8 under the third gate electrode 34c constitute the third cell transistor TR3.

The fifth source/drain regions 26c and 28c, the sixth source/drain region 30c, and the channel layers CH of FIG. 8 under the third gate electrodes 34c are arranged in the second direction (the Y direction) like the third active layer 24c.

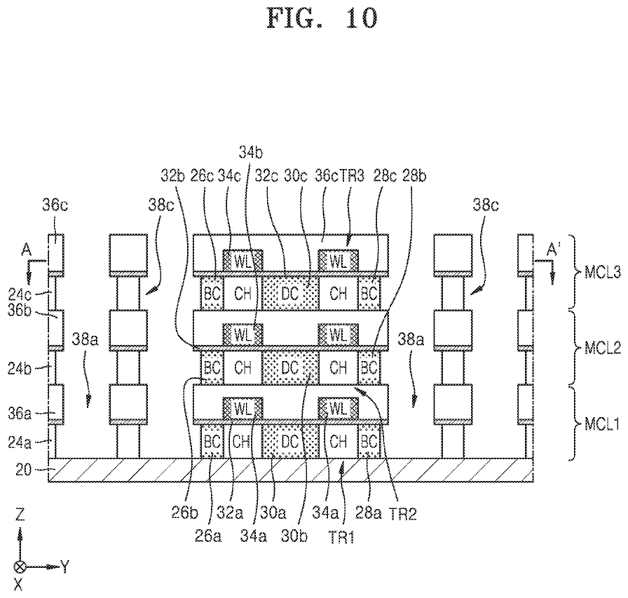

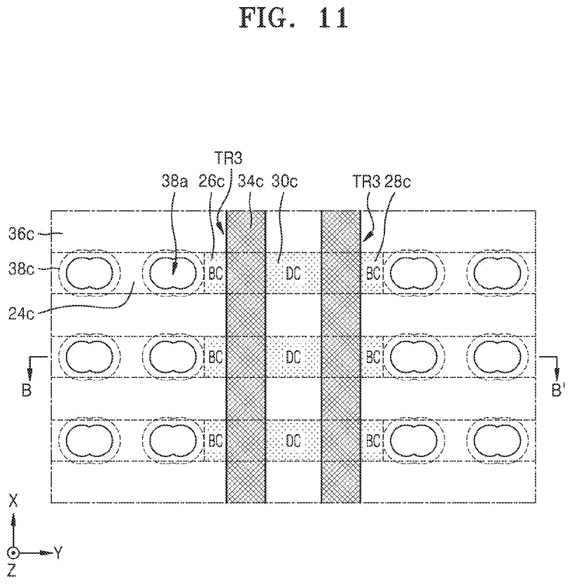

Referring to FIGS. 10 and 11, as illustrated in FIG. 10, the through holes 38a are formed by selectively etching the third interlayer insulating layers 36c, the second interlayer insulating layers 36b, and the first interlayer insulating layers 36a on both sides of the first to third cell transistors TR1, TR2, and TR3. The through hole 38a is formed by forming a photoresist pattern on the third interlayer insulating layer 36c, and then performing anisotropic etching, that is, dry etching, on the third interlayer insulating layer 36c, the second interlayer insulating layer 36b, and the first interlayer insulating layer 36a in the vertical direction (the Z direction) by using the photoresist pattern as an etching mask.

As illustrated in FIG. 11, the through hole 38a may be formed in the embossed shape having the concave portions ca of FIG. 3B and the convex portions cv of FIG. 3B on the X-Y plane. The through hole 38a may be formed by forming a photoresist pattern having an embossed opening on the third interlayer insulating layer 36c on the X-Y plane, and then etching the first to third interlayer insulating layers 36a, 36b, and 36c in the vertical direction (the Z direction) by using the photoresist pattern as the etching mask.

Subsequently, as illustrated in FIGS. 10 and 11, the recess hole 38c is formed by etching each of the first to third active layers 24a, 24b, and 24c exposed through the through hole 38a in the horizontal directions (the X and Y directions). The recess hole 38c may be formed by recessing each of the first source/drain region 26a or 28a, the third source/drain region 26b or 28b, and the fifth source/drain region 26c or 28c from one end of each of the first to third interlayer insulating layers 36a, 36b, and 36c. For example, as shown in FIG. 10, the first to third interlayer insulating layers 36a, 36b, and 36c may protrude in the second direction (the Y direction) from side surfaces of the first source/drain region 26a or 28a, the third source/drain region 26b or 28b, and the fifth source/drain region 26c or 28c.

As illustrated in FIG. 11, the recess hole 38c may be formed in the embossed shape like the through hole 38a. The recess hole 38c may extend in the horizontal directions (the X and Y directions) from the through hole 38a on the X-Y plane.

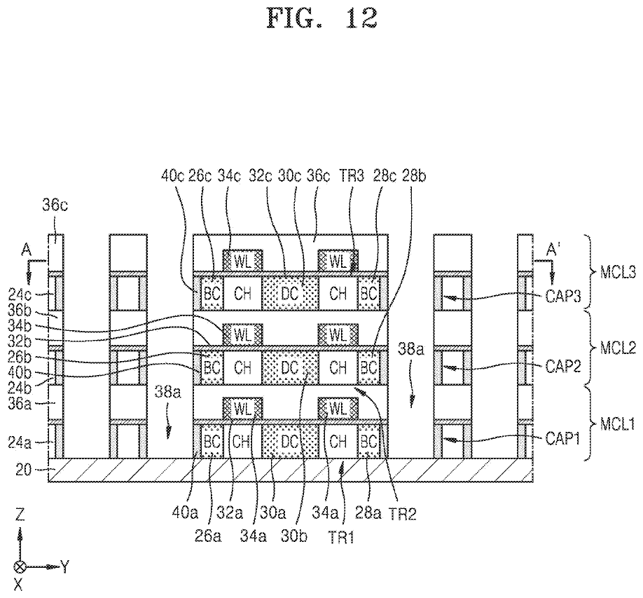

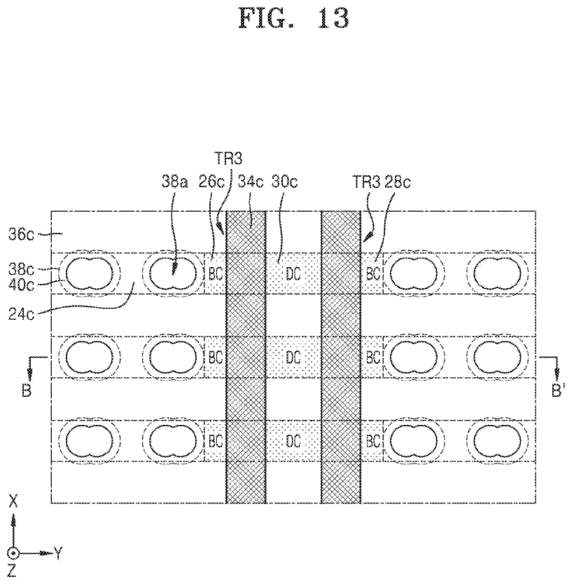

Referring to FIGS. 12 and 13, the first to third sub-electrodes 40a, 40b, and 40c are formed in the recess hole 38c of FIG. 10 as illustrated in FIG. 12. The first sub-electrode 40a may be formed on one side of the first source/drain region 26a or 28a. The second sub-electrode 40b may be formed on one side of the third source/drain region 26b or 28b. The third sub-electrode 40c may be formed on one side of the fifth source/drain region 26c or 28c.

The first to third sub-electrodes 40a, 40b, and 40c may be apart from one another in the third direction (the Z direction). The through hole 38a may be formed in the first to third sub-electrodes 40a, 40b, and 40c. Each of the first to third sub-electrodes 40a, 40b, and 40c may include the first electrode of each of the first to third cell capacitors CAP1, CAP2, and CAP3 of FIG. 2.

As illustrated in FIG. 13, the first to third sub-electrodes 40a, 40b, and 40c may be formed in the recess hole 38c. The through hole 38a may be formed in the first to third sub-electrodes 40a, 40b, and 40c on the X-Y plane. Each of the first to third sub-electrodes 40a, 40b, and 40c may be formed in the embossed shape on the X-Y plane.

As illustrated in FIGS. 12 and 13, the through hole 38a may be formed in the first electrode of each of the first to third sub-electrodes 40a, 40b, and 40c, for example, the first to third cell capacitors CAP1, CAP2, and CAP3. The first electrode of each of the first to third cell capacitors CAP1, CAP2 and CAP3 may constitute the outer electrode on the X-Y plane.

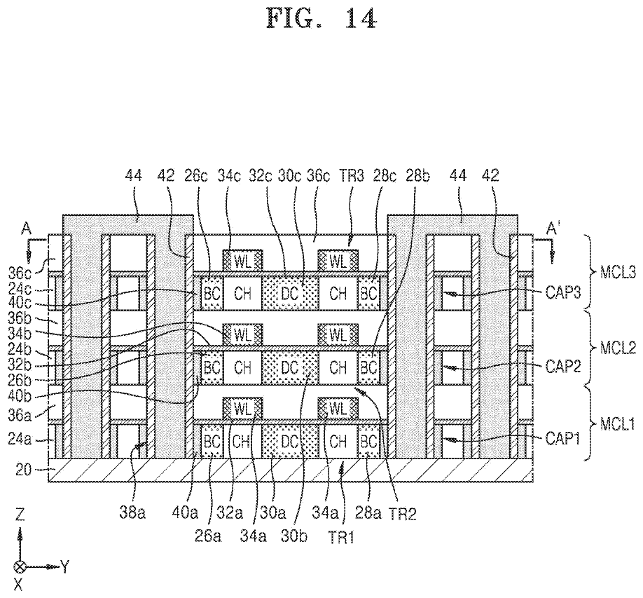

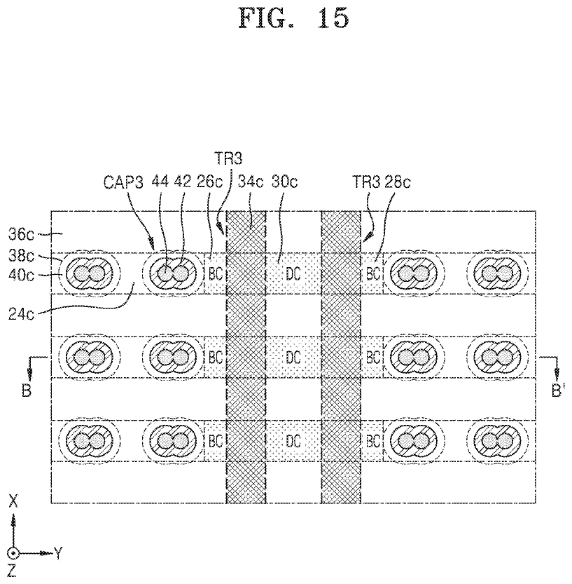

Referring to FIGS. 14 and 15, as illustrated in FIG. 14, the capacitor insulating layer 42 is formed in the through hole 38a. The capacitor insulating layer 42 may extend from the base layer 20 in the vertical direction (the Z direction). The capacitor insulating layer 42 may be formed on one side of each of the first to third sub-electrodes 40a, 40b, and 40c and on one side of each of the first to third interlayer insulating layers 36a, 36b, and 36c.

Subsequently, the second electrode 44 is formed in the capacitor insulating layer 42 while filling the through hole 38a. The second electrode 44 may extend from the base layer 20 in the vertical direction (the third direction).

As illustrated in FIG. 15, the capacitor insulating layer 42 may be formed in the third sub-electrode 40c on the X-Y plane. The capacitor insulating layer 42 may be formed in the embossed shape according to the shape of the third sub-electrode 40c on the X-Y plane. The second electrode 44 may be formed in the capacitor insulating layer 42. The second electrode 44 may be formed in the embossed shape according to the shape of the capacitor insulating layer 42.

As illustrated in FIGS. 14 and 15, the capacitor insulating layer 42 may be formed in the first to third sub-electrodes 40a, 40b, and 40c. The second electrode 44 may be formed in the capacitor insulating layer 42 while filling the through hole 38a. The second electrode 44 may constitute the inner electrode on the X-Y plane. Through the above-described process, the first to third cell capacitors CAP1, CAP2, and CAP3 may be completed.

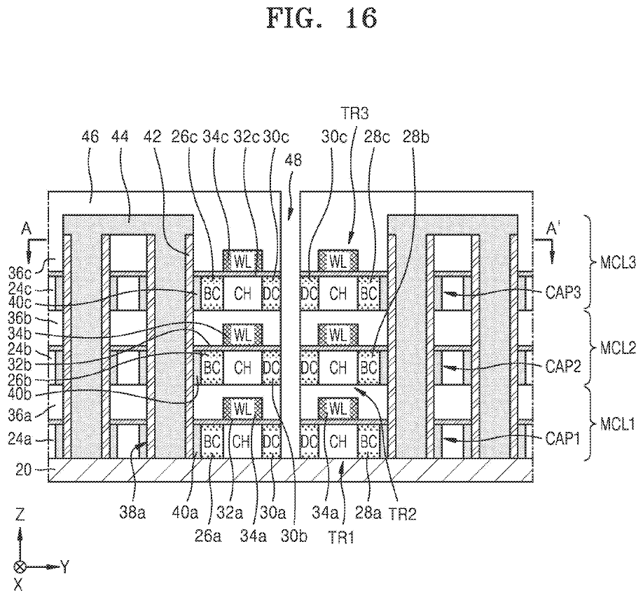

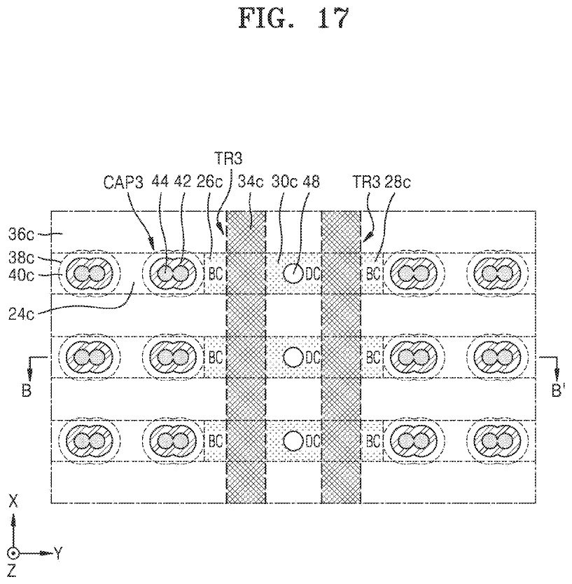

Referring to FIGS. 16 and 17, as illustrated in FIG. 16, a protective insulating layer 46 is formed on the third memory cell level layer MCL3. Subsequently, a bit line contact hole 48 is formed through the protective insulation layer 46, the first to third gate insulating layers 32a, 32b, and 32c, the sixth source/drain region 30c, the fourth source/drain region 30b, and the second source/drain region 30a.

The bit line contact hole 48 extends to the base layer 20 in the vertical direction (the Z direction). The bit line contact hole 48 may be formed through the center of the sixth source/drain region 30c, the fourth source/drain region 30b, and the second source/drain region 30a. As illustrated in FIG. 17, the bit line contact hole 48 may be formed in the sixth source/drain region 30c on the X-Y plane. The bit line contact hole 48 may be formed by using a photolithography process.

Subsequently, the bit line 50 is formed in the bit line contact hole 48 of FIGS. 16 and 17, as illustrated in FIGS. 2 and 3A to 3C. Subsequently, as illustrated in FIG. 2, the bit line strap 52 is formed on the bit line 50 to complete the 3D semiconductor memory device EX1.

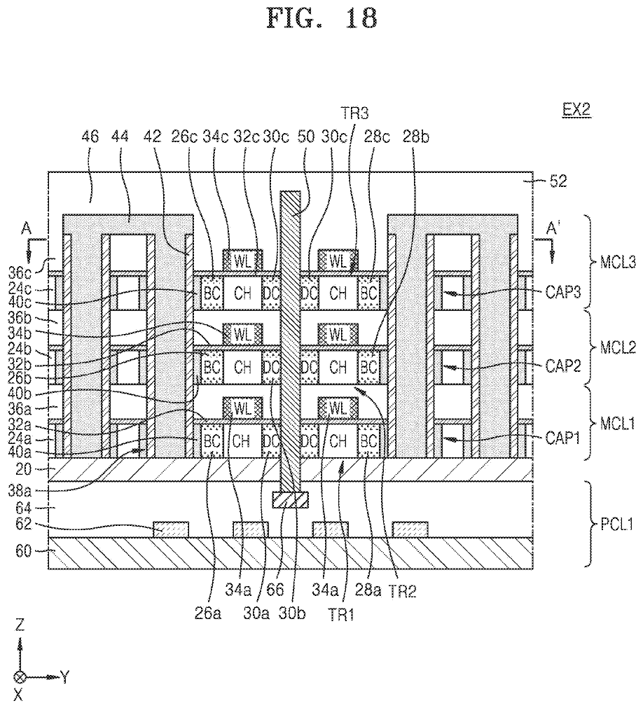

FIG. 18 is a cross-sectional view of a main part of a 3D semiconductor memory device EX2 according to an embodiment.

Specifically, the 3D semiconductor memory device EX2 may be substantially the same as the 3D semiconductor memory device EX1 of FIG. 2 except that a peripheral circuit level layer PCL1 is further formed under the base layer 20 and a bit line strap is not formed. The plan view of the main part along the line A-A′ of FIG. 18 may be the same as that of FIG. 3A. In FIG. 18, description previously given with reference to FIGS. 2 to 3C is simply given or omitted.

The 3D semiconductor memory device EX2 includes the peripheral circuit level layer PCL1 formed under the base layer 20. The peripheral circuit level layer PCL1 may include a peripheral circuit transistor 62, a peripheral interlayer insulating layer 64, and a peripheral wiring layer 66. The peripheral circuit transistor 62 may be formed on a substrate 60. The substrate 60 may be or include a semiconductor substrate, for example, a silicon substrate. The peripheral wiring layer 66 may be directly connected to the bit line 50.

The 3D semiconductor memory device EX2 includes the peripheral circuit level layer PCL1 formed under the base layer 20, and directly connects the bit line 50 to the peripheral wiring layer 66. Accordingly, in the 3D semiconductor memory device EX2, wiring resistance may be reduced by removing the bit line strap and directly connecting the bit line 50 to the peripheral wiring layer 66.

While the inventive concept has been particularly shown and described with reference to embodiments thereof, it will be understood that various changes in form and details may be made therein without departing from the spirit and scope of the inventive concept.

What is claimed is:

1. A three-dimensional (3D) semiconductor memory device comprising a plurality of memory cells stacked in a vertical direction, each of the plurality of memory cells including a cell transistor and a cell capacitor, wherein the cell capacitor comprises:
a first electrode connected to a first source/drain region of the cell transistor, wherein a through hole is formed in the first electrode and the inner surface of the first electrode is formed in a shape having concave portions and convex portions in plan view;
a capacitor insulating layer in the through hole; and
a second electrode in the capacitor insulating layer and filling the through hole.

2. The 3D semiconductor memory device of claim 1, wherein, in the through hole, a plurality of sub-through holes partially overlap one another on a plane in one direction, and wherein each of the plurality of sub-through holes has a symmetrical geometric shape.

3. The 3D semiconductor memory device of claim 1, wherein the concave portions and the convex portions may be formed on both an outer surface and an inner surface of the first electrode in plan view.

4. The 3D semiconductor memory device of claim 1, wherein each of the capacitor insulating layer and the second electrode is formed in a shape corresponding to the shape of the first electrode in plan view.

5. The 3D semiconductor memory device of claim 1, wherein the first electrode constitutes an outer electrode and the second electrode constitutes an inner electrode in plan view.

6. The 3D semiconductor memory device of claim 1, wherein the cell capacitor comprises a single first electrode, a single capacitor insulating layer, and a single second electrode in plan view.

7. The 3D semiconductor memory device of claim 1, wherein the cell transistor further comprises a second source/drain region and the second source/drain region is connected to a bit line.

8. The 3D semiconductor memory device of claim 1, wherein the capacitor insulating layer comprises a ferroelectric layer including a hafnium-based oxide layer including at least one dopant among zirconium (Zr), silicon (Si), aluminum (Al), yttrium (Y), gadolinium (Gd), lanthanum (La), scandium (Sc), and strontium (Sr).

9. The 3D semiconductor memory device of claim 1, wherein the capacitor insulating layer comprises a stacked structure of two or more types of ferroelectric layers or a stacked structure of a ferroelectric layer and a dielectric layer.

10. A three-dimensional (3D) semiconductor memory device comprising a plurality of memory cells stacked in a vertical direction, the plurality of memory cells including a plurality of cell transistors and a plurality of cell capacitors, wherein the plurality of cell capacitors comprises a plurality of sub-electrodes apart from one another in a vertical direction, wherein a through hole is formed in the plurality of sub-electrodes, and wherein an inner surface of each of the plurality of sub-electrodes is formed in a shape having concave portions and convex portions in plan view, and
wherein the plurality of cell capacitors comprises:
a capacitor insulating layer extending in the through hole in the vertical direction; and
a second electrode extending in the capacitor insulating layer in the vertical direction and filling the through hole.

11. The 3D semiconductor memory device of claim 10, wherein each of the capacitor insulating layer and the second electrode is formed in a shape corresponding to the shape of each of the plurality of sub-electrodes in plan view.

12. The 3D semiconductor memory device of claim 10, wherein the plurality of cell transistors are apart from one another in the vertical direction and each of the plurality of cell transistors is connected to a bit line extending in the vertical direction on one side thereof.

13. The 3D semiconductor memory device of claim 12, further comprising a bit line strap connected to the bit line, the bit line strap extending in a horizontal direction.

14. The 3D semiconductor memory device of claim 12, wherein the plurality of cell capacitors are apart from one another in the vertical direction, and
wherein each of the plurality of cell capacitors is connected to a corresponding cell transistor of the plurality of cell transistors on the other side of the corresponding cell transistor.

15. The 3D semiconductor memory device of claim 10, wherein the plurality of cell transistors comprises source/drain regions arranged in a horizontal direction and a channel layer arranged between the source/drain regions in the horizontal direction, and
wherein in plan view, center lines of the source/drain regions and the channel layer coincide with center lines of the plurality of cell capacitors, the center lines of the source/drain regions and the channel layer and the center lines of the plurality of cell capacitors extending in the horizontal direction.

16. The 3D semiconductor memory device of claim 15, wherein the source/drain regions comprise a first source/drain region and a second source/drain region, wherein the first source/drain region is connected to a bit line, and
wherein the second source/drain region is connected to a corresponding sub-electrode among the plurality of sub-electrodes.

17. A three-dimensional (3D) semiconductor memory device comprising:
a base layer; and
a plurality of memory cell level layers apart from one another and stacked on the base layer in a vertical direction, wherein the plurality of memory cell level layers comprises a plurality of cell transistors and a plurality of cell capacitors apart from one another in the vertical direction, wherein the plurality of cell transistors comprise:
source/drain regions;
channel layers arranged among the source/drain regions; and
gate electrodes arranged on the channel layers,
wherein each of the plurality of cell capacitors comprises a plurality of sub-electrodes apart from one another in a vertical direction, wherein a through hole is formed in the plurality of sub-electrodes, and wherein each of the plurality of sub-electrodes is formed in a shape having concave portions and convex portions in plan view, and
wherein the plurality of cell capacitors comprise:
a capacitor insulating layer extending in the through hole in the vertical direction; and
a second electrode extending in the capacitor insulating layer in the vertical direction and filling the through hole.

18. The 3D semiconductor memory device of claim 17, wherein each of the channel layers comprises a semiconductor material, a two-dimensional (2D) material, or an oxide semiconductor material.

19. The 3D semiconductor memory device of claim 17, wherein each of the plurality of cell transistors is connected to a bit line extending in the vertical direction on one side, and
wherein a peripheral circuit level layer is further formed under the base layer.

20. The 3D semiconductor memory device of claim 17, wherein each of the capacitor insulating layer and the second electrode is formed in a shape corresponding to the shape of each of the plurality of sub-electrodes in plan view.
